(19) United States
(12) Patent Application Publication
(10) Pub. No.: US 2026/0142128 A1
(43) Pub. Date: May 21, 2026

(54) DIFFUSION PLATE

(71) Applicant: NxEdge, Inc., Boise, ID (US)

(72) Inventor: Koda Boldt, Nampa, ID (US)

(21) Appl. No.: 19/396,860

(22) Filed: Nov. 21, 2025

Related U.S. Application Data
(60) Provisional application No. 63/723,271, filed on Nov. 21, 2024.

(51) Int. Cl. H01J 37/32; B28B 1/00; B33Y 10/00; B33Y 80/00

(52) U.S. Cl. CPC H01J 37/3244; B28B 1/001; B33Y 10/00; B33Y 80/00; H01J 2237/332

(57) ABSTRACT

A porous media transport diffusion plate is provided. The porous media diffusion plate has an outer support perimeter configured to be coupled to a process chamber that delivers a flow of material through the porous media transport diffusion plate; and a built porous media transport layer has a plurality of lattice structures contained in the outer support perimeter to receive and diffuse the flow of material. The lattice structure is formed by a plurality of struts and plurality of ribs coupled by joints and connection points.

### CROSS-REFERENCE TO RELATED PATENT APPLICATIONS

This application claims the benefit of U.S. Provisional Patent Application No. 63/723,271 filed Nov. 21, 2024, the entire contents of which is incorporated by reference herein.

### BACKGROUND

Diffusion plates are used with gaseous processes including plasma deposition, such as for example, in thin film manufacturing. The diffusion plates enhance a more uniform distribution of the plasma over the substrate onto which the deposition material is being deposited. The more uniform the distribution the higher the yield as the deposition material is more consistent over the surface area of the substrate. In other words, diffusion plates enhance the deposition of the material on the substrate by controlling the flow and density of ions and particles from the plasma plume to the substrate surface, which helps achieve the desired film characteristics, such as thickness, composition, and microstructure.

One function of the diffusion plate is to diffuse the incoming plasma, which often exhibits non-uniform characteristics. When plasma enters the deposition chamber, it can have varying densities and energy distributions. The diffusion plate acts as a barrier that alters the trajectories of charged particles, facilitating a more even distribution across the substrate surface. This results in a more uniform deposition of materials, which is beneficial for applications requiring a more precise control over film properties.

Diffusion plates are made from a material capable of withstanding the manufacturing chamber environment. The diffusion plates have a plurality of holes formed in the diffusion plate to allow the plasma with the deposition material contained therein to travel through the diffusion plate. The plurality of holes enhance the uniformity of the distribution of the flow over the substrate on which the material is being deposited. The size, shape, and placement of the plurality of holes over the diffusion plate helps to control the flow of the ions and particles over the surface of the substrate. The plurality of holes also mitigates shadowing by increasing the uniformity of the flow over the substrate, where shadowing occurs when portions of the substrate receive less deposition material due to shadows in the process chamber of the substrate.

Conventionally, the plurality of holes in the diffusion plate are formed by taking a solid diffusion plate and creating the holes via drilling techniques such as, for example, drilling, laser cutting, or the like. In other words, the holes are physically machined into material to form the diffusion plate. Conventional techniques to make the plurality of holes to form the diffusion plate, while predictable, are limited by physical restrictions.

Thus, against this background, improved diffusion plates are desirous.

### SUMMARY

This Summary is provided to introduce a selection of concepts in a simplified form that are further described below in the Detailed Description. This Summary, and the foregoing Background, is not intended to identify key aspects or essential aspects of the claimed subject matter. Moreover, this Summary is not intended for use as an aid in determining the scope of the claimed subject matter.

The technology of the present application provides a porous media transport diffusion plate. The porous media diffusion plate has an outer support perimeter configured to be coupled to a process chamber that delivers a flow of material through the porous media transport diffusion plate; and a built porous media transport layer comprising a plurality of lattice structures contained in the outer support perimeter to receive and diffuse the flow of material.

These and other aspects of the present system and method will be apparent after consideration of the Detailed Description and Figures herein.

### BRIEF DESCRIPTION OF THE DRAWINGS

Non-limiting and non-exhaustive embodiments of the present invention, including the preferred embodiment, are described with reference to the following figures, wherein like reference numerals refer to like parts throughout the various views unless otherwise specified.

FIG. 1A depicts a detail of a hole through a diffusion plate.

FIG. 1B depicts a detail of a built or engineered porous transport layer and a grown porous transport layer.

FIG. 2 depicts a side-by-side view of flow through a process chamber with a diffusion plate consistent with the technology of the present application and a process chamber with a conventional diffusion plate.

FIG. 3 depicts lattice structures for a diffusion plate using a built porous transport layer consistent with the technology of the present application.

FIG. 4 depicts a plane view of a built porous transport layer diffusion plate consistent with the technology of the present application and details thereof.

FIG. 5 depicts a plane view of a built porous transport layer diffusion plate consistent with the technology of the present application and details thereof.

FIG. 6 depicts additional lattice structure shapes and configurations for consistent with the technology of the present application.

### DETAILED DESCRIPTION

Embodiments are described more fully below with reference to the accompanying figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense. Moreover, the technology of the present application will be described with relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

Substrates or workpieces often have one or more surfaces that require a coat of material on the surface. The coat of material may be to improve wear, thermal, or the like, or some combination of characteristics. One exemplary way to coat a substrate surface is to propel the material (or deposition material) towards the surface of the substrate at a velocity, size, and/or energy sufficient for the material to adhere, or stick, to the surface, such as may be done using conventional deposition technology. Depositing material on a surface, however, has a number of variables that impact the overall yield, such as, for example, the velocity at which the material impacts the surface, the uniformity of which the material is distributed over the surface, etc. The variables make the deposition of material on the surface of a substrate difficult to control and manage with precision.

Given the difficulties of depositing the material on the surface, the industry is continually developing improvements to the process of depositing material. The industry eventually developed diffusion plates. A diffusion plate is a plate that has a plurality of pores formed into the diffusion plate. The diffusion plate is typically formed from a solid piece of material, such as an erosion resistant metal or ceramic. The solid piece of material has the plurality of pores (or holes) formed in the material using conventional, although cumbersome, technologies to make pores, such as, for example, mechanically drilling the holes. A diffusion plate with a plurality of pores machined or drilled in the plate may be referred to as a showerhead. The placement of the plurality of pores as well as the shape of each pore are highly designed and difficult to machine.

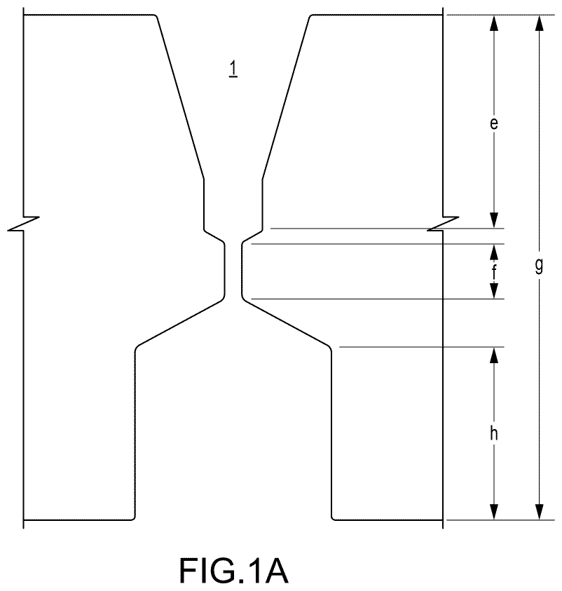

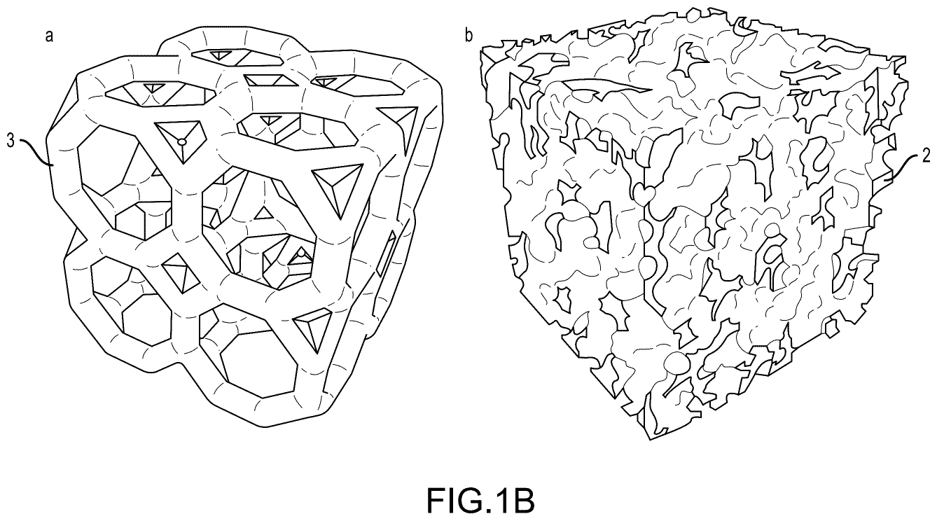

The shape of each pore through the diffusion plate is designed to provide certain features regarding the flow of material through the plate. Thus, the designs are often complex and require complex drilling techniques, such as drilling multiple sized holes from opposite sides of the diffusion plate. An exemplary pore or hole 1 through a diffusion plate is shown in FIG. 1A. As can be seen, the hole has multiple diameters and angulations making the formation of the pore, or hole, complex. While diffusion plates provide for a more controlled and even flow of the material to the surface of the substrate, improved diffusion plates are needed as the demands on the characteristics of the coat become more precise. In other words, the cost and complexity to form the pores is becoming a limiting feature in certain aspects.

The technology of the present application provides for using a porous transport medium as the diffusion plate. A porous transport medium may be formed by growing the porous transport medium (or gPTL) or building the porous transport medium (or bPTL), which may be referred to as an engineered porous transport medium also. FIG. 1B shows a gPTL 2 and a bPTL 3 for comparison. A gPTL generally provides for a random, orientation of the pores or openings although a gPTL has a predictable porosity. Conversely, a bPTL is constructed with a lattice structure 4 as described below. The lattice structure 4 has a variable geometry and can be designed with specifically arranged openings and pores such that the flow of material through the bPTL can be simulated allowing optimization of the design for the characteristics of the plume and material being applied to the surface of the workpiece or substrate.

The bPTL may be formed from an additive manufacturing process. For example, in certain embodiments, the bPTL may be manufactured using 3d printing technology. The bPTL may be formed from metals, such as, for example, aluminum, nickel, and stainless steel; ceramics, such as, for example, silicon carbide. Other materials may include quartz.

The bPTL may be specifically designed, as mentioned above, to even the flow of plasma with material over the surface of the substrate. In certain aspects, the even, constant flow of the plasma over the substrate provides for a uniform distribution of material on the surface. In other aspects, the even, constant flow minimizes turbulence that decreases particle agglomeration and defects, and the like. The even, constant flow generally should increase the yield and decrease the need to work the surface subsequent to the deposit of the coat on the surface. Decreasing the need to work the surface after the deposit of material may reduce post process polishing, machining, chemical etching, or the like. In certain aspects, the even, constant flow may minimize thermal stress on the substrate, which also can impact and increase yield. The technology of the present application uses a porous media diffusion plate that reduces the inconsistencies in the wafer deposition process. While not being bound to a particular theory, it is believed the porous media more effectively diffuses a working fluid across a desired region to minimize the variance of particle deposition, which should increase the ability to precisely control the thickness of the deposited material as well as the uniformity of the thickness.

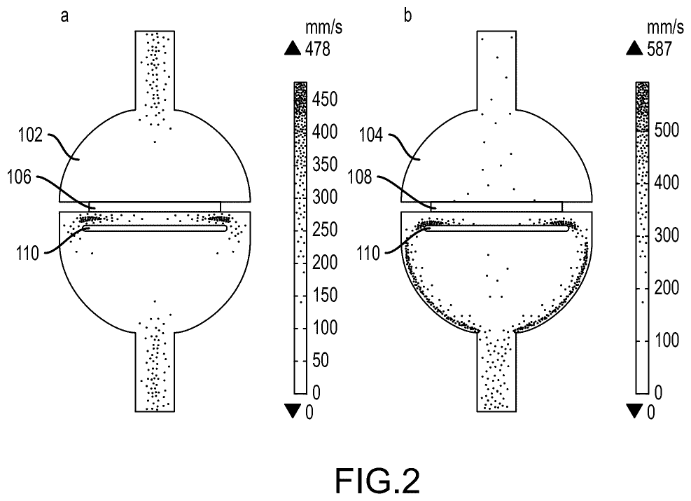

As mentioned above, yield for coated substrates/workpieces increases if the material is deposited uniformly, which results in a uniform thickness on the surface, without agglomeration of particles. When the coat is not of a uniform thickness and/or has particle agglomeration and build up, the coat is more likely to have defects that result in overall inconsistencies in the coated substrate. FIG. 2 shows a side-by-side flow spectral image of flow through a first process chamber 102 and a second process chamber 104. The first process chamber 102 has a bPTL diffusion plate 106 and the second process chamber 104 has a conventionally drilled showerhead diffusion plate 108. Both process chambers include a substrate 110, or workpiece 110. The first process chamber 102, as can be seen, has a relatively even flow of the plume over the process chamber. The second process chamber 104 has a relatively less even flow of the plume over the process chamber, and more importantly, relatively significant deviations of flow over the workpiece.

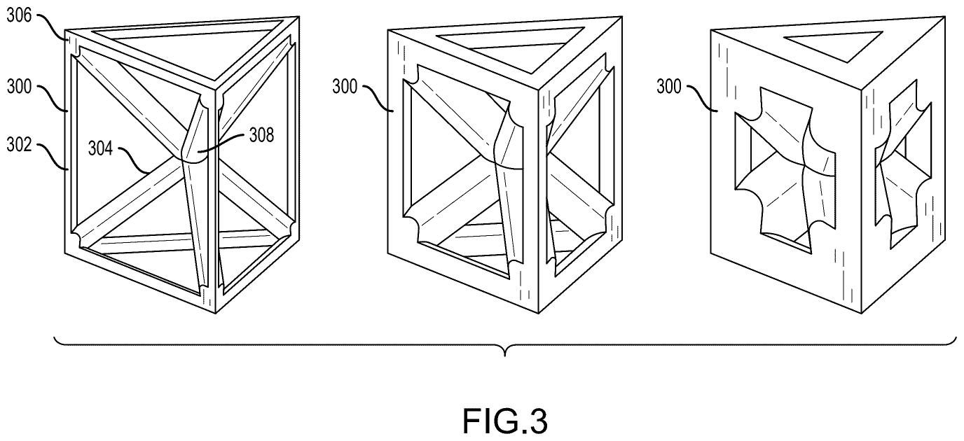

The bPTL diffusion plate 106 is generally formed from an additive manufacturing process, such as, for example, 3d printing. FIG. 3 shows a possible lattice structure 300 for bPTL diffusion plate. The lattice structure 300, in this FIG. 3, is but one possible geometry for the bPTL. In this example, the lattice structure 300 comprises a plurality of outer lattice structs 302 and a plurality of inner lattice ribs 304. In certain embodiments, the lattice structure 300 may comprise outer lattice structs 302 only, inner lattice ribs 304 only, or a combination thereof as shown, see for example, lattice structure 4 in FIG. 2. The outer lattice structs 302 are connected at joints 306 (or nexuses 306) and, in this example, form the outer three-dimensional shape of the lattice structure 300, which in this case is a triangular shaped top and bottom with rectangular sides. The joints 306 are shown as a solid joint, but could have one or more channel to facilitate flow. The inner lattice ribs 304 extend inwardly from the outer lattice structure 302. As shown the inner lattice ribs 304 are connected to the outer lattice structs 302 at joints 306 and extend inwardly to a connection point 308 (or vertices 308), which in this exemplary embodiment comprises a single connection point 308 at the geometric center of the lattice structure. Again, the connection point is shown as solid but could have one or more channels to facilitate flow.

The lattice structure 300 may be designed with a specific porosity. Also, the porosity of the lattice structure 300 is controllable in one way by changing the thickness and/or amount of either or both of the outer lattice structs 302 or inner lattice ribs 304. The thickness (and/or amount) of the outer lattice structs 302 and inner lattice ribs 304 influence the porosity of the lattice structure 300 because as the thickness (and/or amount) of either, the overall porosity of the lattice structure 300 decreases. FIG. 3 is illustrative of how increasing the thickness of the structs and ribs can cause the porosity of the lattice structure to decrease. Increasing the amount of structs and ribs would provide a similar effect as it would take up more volume. From left to right, the different thicknesses may represent a high porosity, an intermediate porosity, and low porosity.

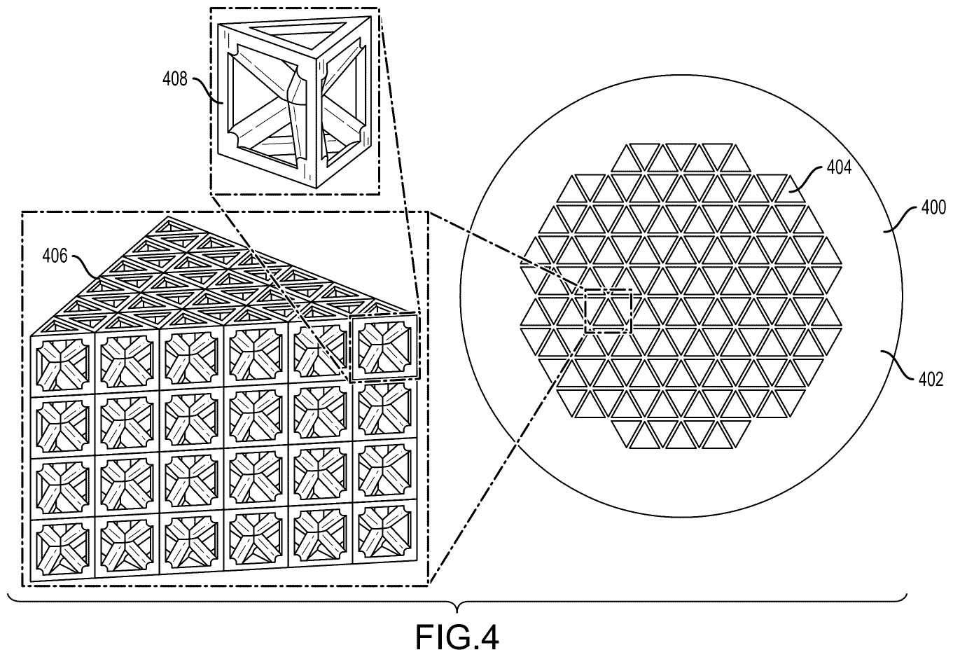

FIG. 4 shows the lattice structure 300 in a bPTL diffusion plate 400. The bPTL diffusion plate 400 includes the bPTL 402 formed from a plurality of lattice structures 300 formed into a tessellation arrangement, which is pattern of shapes that fit together on a plane without gaps or overlaps. As shown, the bPTL is specifically a triangular tessellation although other configurations are possible. The diffusion plate 400 also includes an outer support perimeter 404. The bPTL 402 is contained in an outer support perimeter 404, which has a circular cross section in this exemplary embodiment. Detail 406 of the bPTL 402 shows the plurality of lattice structures 300 stacked both vertically and horizontally. Detail 408 shows the lattice structure 300 individually, which is the intermediate porosity structure in FIG. 3.

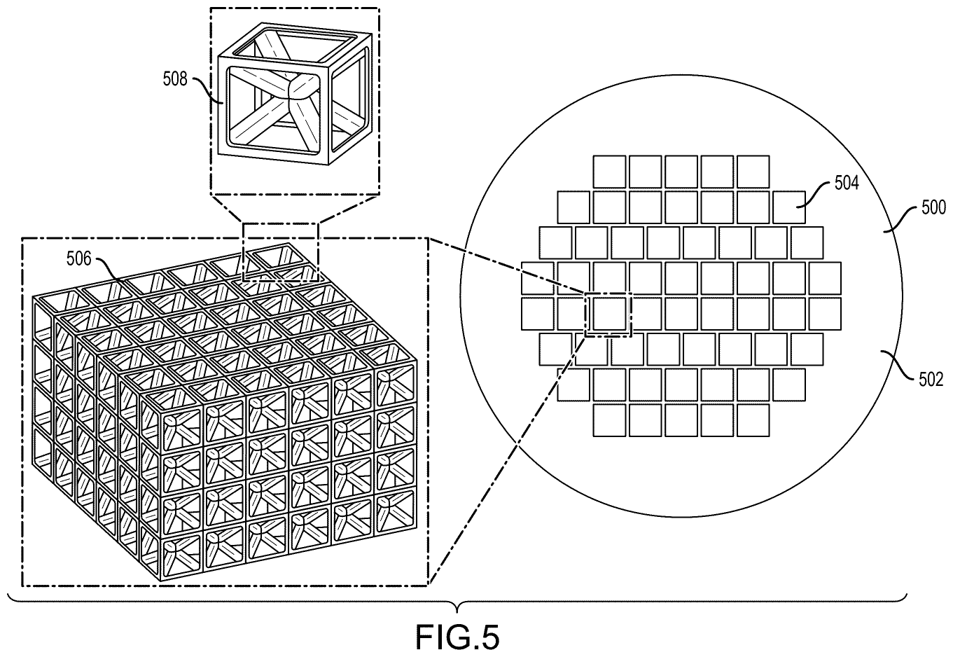

FIG. 5 shows a second bPTL diffusion plate 500. The bPTL diffusion plate 500 comprises a plurality of lattice structures 502 formed into a quadrilateral tessellation arrangement. The diffusion plate 500 includes an outer support perimeter 504, which again is shown as circular, but could be other shapes. The bPTL 506 is contained by the outer support perimeter 504, which would mount to holders in the process chamber as shown in FIG. 2. Detail 508 of the bPTL 506 shows the plurality of lattice structures 502 stacked both vertically and horizontally in a quadrilateral arrangement. Detail 510 shows an individual lattice structure 502, which is a quadrilateral, specifically cubic, shape. The lattice structure 502 includes a plurality of outer lattice structs 512 connected at joints 514 and a plurality of inner lattice ribs 516 coupled to the outer lattice structs 512 at the joints 514 and extending to a singular connection point 518. The connection point 518 may in certain embodiments be multiple connection points elsewhere than the geometric center.

With reference back to FIG. 2, the diagram shows the flow characteristics of the process chambers with the bPTL v. a conventional showerhead. The chart 1 below shows an exemplary model of the flow over the substrate or workpiece, which demonstrates the superiority of the bPTL diffusion plates over conventional showerheads. With flow characteristics may be further refined by the lattice structure geometries, which it is assumed will further increase and optimize the designs.

CHART 1

| | [symbol] | [symbol] | |
|---|---|---|---|
| Volumetric | Vertical Velocity | Vertical Velocity | Percent |
| Flow Rate | Variance | Variance | Decrease |
| [L/ [symbol] ] | [symbol] | [symbol] | [%] |
| 5 | 0.009720 | [symbol] | 99.97 |
| 15 | 0.08204 | 266.6 | 99.97 |
| 50 | 0.7521 | 2880 | 99.97 |
| 150 | [symbol] | 26440 | 99.98 |

[symbol]

indicates data missing or illegible when filed

As the chart demonstrates, the flow variance with the bPTL shows a reduced amount of change in flow over the surface of the substrate in this model.

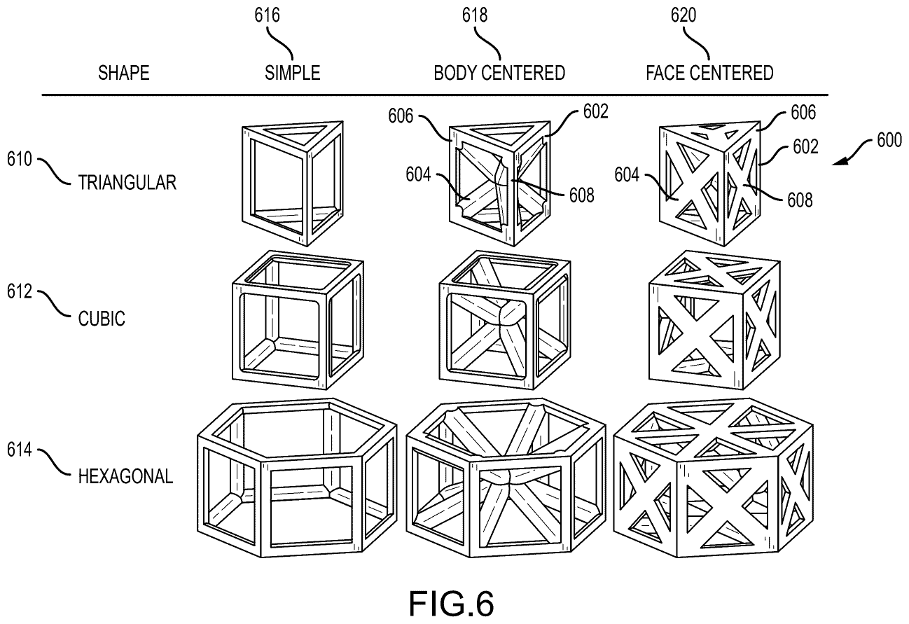

While some of the bPTL lattice structures are shown above in exemplary embodiments, other lattice structures are possible. FIG. 6 shows several possible lattice structures 600. The lattice structures comprise a plurality of struts 602 and, optionally, a plurality of ribs 604. The plurality of struts 602 are coupled at joints 606 and the plurality of ribs 604, should they exist, are coupled to the plurality of struts 602 at joints 606 and coupled to each other at connection points 608. The lattice structures may be polyhedrons such as those shown, which include a triangular structure 610, a cubic structure 612, and a hexagonal structure 614, although other shapes are possible. The strut and rib configuration for each structure includes a simple configuration 616, a body centered configuration 618, and a face centered configuration 620, although other configurations are possible. For example, the strut and rib configuration could combine the body centered configuration and the face centered configuration in certain embodiments.

Although the technology has been described in language that is specific to certain structures, materials, and methodological steps, it is to be understood that the invention defined in the appended claims is not necessarily limited to the specific structures, materials, and/or steps described. Rather, the specific aspects and steps are described as forms of implementing the claimed invention. Since many embodiments of the invention can be practiced without departing from the spirit and scope of the invention, the invention resides in the claims hereinafter appended. Unless otherwise indicated, all numbers or expressions, such as those expressing dimensions, physical characteristics, etc. used in the specification (other than the claims) are understood as modified in all instances by the term “approximately.” At the very least, and not as an attempt to limit the application of the doctrine of equivalents to the claims, each numerical parameter recited in the specification or claims which is modified by the term “approximately” should at least be construed in light of the number of recited significant digits and by applying ordinary rounding techniques. Moreover, all ranges disclosed herein are to be understood to encompass and provide support for claims that recite any and all subranges or any and all individual values subsumed therein. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

What is claimed is:

1. A porous media transport diffusion plate, comprising:
an outer support perimeter configured to be coupled to a process chamber that delivers a flow of material through the porous media transport diffusion plate; and
a built porous media transport layer comprising a plurality of lattice structures contained in the outer support perimeter to receive and diffuse the flow of material.

2. The porous media transport diffusion plate of claim 1 wherein the plurality of lattice structures comprise a plurality of lattice struts and a plurality of joints that couple the plurality of lattice struts.

3. The porous media transport diffusion plate of claim 2 wherein the plurality of lattice structures comprise a plurality of lattice ribs, where the plurality of lattice ribs are coupled to the plurality of lattice structs at the plurality of joints.

4. The porous media transport diffusion plate of claim 3 wherein the plurality of lattice ribs are coupled at a connection point.

5. The porous media transport diffusion plate of claim 3 wherein the plurality of lattice ribs are coupled at a plurality of connection points.

6. The porous media transport diffusion plate of claim 2 wherein the porosity of the porous media transport diffusion plate is controlled, in part, by the thickness of the plurality of lattice struts.

7. The porous media transport diffusion plate of claim 3 wherein the porosity of the porous media transport diffusion plate is controlled, in part, by the thickness of the plurality of lattice ribs.

8. The porous media transport diffusion plate of claim 1 wherein the built porous media transport layer comprises a tessellation.

9. The porous media transport diffusion plate of claim 1 wherein the plurality of lattice structures each form a polyhedron.

10. The porous media transport diffusion plate of claim 9 wherein the polyhedron is selected from a group of polyhedrons consisting of a triangular prism, cuboid, rectangular prism, a octahedron, a dodecahedron, or a tetrahedron.

11. The porous media transport diffusion plate of claim 2 wherein the plurality of lattice struts form simple configurations.

12. The porous media transport diffusion plate of claim 3 wherein the plurality of lattice struts and the plurality of lattice ribs form body centered configurations.

13. The porous media transport diffusion plate of claim 3 wherein the plurality of lattice struts and the plurality of lattice ribs form face centered configurations.

14. A method of making a porous media transport diffusion plate, comprising:
providing an outer support perimeter configured to be coupled to a process chamber that delivers a flow of material through the porous media transport diffusion plate; and
building through an additive manufacturing process a built porous media transport layer having a plurality of lattices contained in the outer support perimeter wherein the plurality of lattices have a porosity to receive the flow of material and diffuse the flow of material over a workpiece.

15. The method of claim 14 wherein the additive manufacturing process is 3d printing.

16. The method of claim 14, wherein the additive manufacturing process builds the porous media transport layer using a ceramic material.

17. The method of claim 14 wherein the building the plurality of lattices comprises building a plurality of struts, a plurality of ribs, or a combination thereof, wherein the plurality of struts and the plurality of ribs are connected at a plurality of vertices and nexuses.

18. The method of claim 14 wherein the porosity of the plurality of lattices form a quadrilateral tessellation arrangement.

19. A porous media transport diffusion plate, comprising:
an outer support perimeter configured to be coupled to a process chamber that delivers a flow of material through the porous media transport diffusion plate; and
a built porous media transport layer, wherein the built porous media transport layer comprises
a plurality of struts formed by an additive manufacturing process,
a plurality of ribs formed by the additive manufacturing process,
a plurality of joints, a plurality of connection points, or a combination thereof formed by the additive manufacturing process that couple the plurality of struts and the plurality of ribs to form a lattice structure.

20. The porous media transport diffusion plate of claim 19, wherein the lattice structure is a quadrilateral tessellation arrangement.
